(19) United States
(12) Patent Application Publication
(10) Pub. No.: US 2026/0329540 A1
(43) Pub. Date: Oct. 22, 2026

(54) COMPUTE-IN-MEMORY CELL ARCHITECTURE FOR IN-MEMORY COMPUTATION

(71) Applicant: Koushik Krishnan, Saratoga, CA (US)

(72) Inventor: Koushik Krishnan, Saratoga, CA (US)

(21) Appl. No.: 19/649,196

(22) Filed: Apr. 16, 2026

Related U.S. Application Data
(60) Provisional application No. 63/791,110, filed on Apr. 18, 2025.

(51) Int. Cl. G06F 7/523; G11C 11/401; G11C 11/412; H03K 19/20

(52) U.S. Cl. CPC G06F 7/523; G11C 11/401; G11C 11/412; H03K 19/20

(57) ABSTRACT

Compute-in-memory cell architecture for in-memory computation is provided. A compute-in-memory cell includes a memory element to store a weight value. The compute-in-memory cell further includes a logic element coupled to a read line of the memory element. The logic element receives an input data value from an external data line. The logic element generates an output signal based on the input data value and the weight value. The output signal represents a result of a one-bit multiplication operation between the weight value and the input data value.

### CROSS-REFERENCE TO RELATED APPLICATIONS/INCORPORATION BY REFERENCE

This application claims priority to U.S. Provisional Patent Application Ser. No. 63/791,110 filed on Apr. 18, 2025, the entire content of which is hereby incorporated herein by reference.

### TECHNICAL FIELD

The disclosure relates to memory architecture and more particularly, to compute-in-memory cell architecture for in-memory computation.

### BACKGROUND

Memory technologies such as dynamic random access memory (DRAM) and static random access memory (SRAM) have been developed to address various performance and density requirements in computing systems. DRAM cells typically utilize a transistor-capacitor structure that provides high density but requires periodic refresh operations, while SRAM elements employ latch-based structures that offer faster access times without refresh requirements but at lower density. As computational workloads have increased, particularly in applications involving matrix operations and neural network computations, there has been growing interest in reducing the data movement overhead between memory and processing units. Various approaches have been explored to bring computational capabilities closer to where data is stored, aiming to improve energy efficiency and throughput for data-intensive operations.

### SUMMARY

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

In various embodiments of the disclosure, a compute-in-memory cell is described. The compute-in-memory cell includes a memory element configured to store a weight value. The compute-in-memory cell further includes a logic element coupled to a read line of the memory element. The logic element is configured to receive an input data value from an external data line. The logic element is also configured to generate an output signal based on the input data value and the weight value. The output signal represents a result of a one-bit multiplication operation between the weight value and the input data value.

In various embodiments of the disclosure, a method for performing compute-in-memory operations is described. The method includes storing a weight value in a memory element of a compute-in-memory cell. The method further includes receiving an input data value from an external data line at a logic element coupled to a read line of the memory element. The method also includes generating, by the logic element, an output signal based on the input data value and the weight value. The output signal represents a result of a one-bit multiplication operation between the weight value and the input data value.

In various embodiments of the disclosure, an application-specific integrated circuit (ASIC) for compute-in-memory operations is described. The ASIC includes an arrangement of an array of compute-in-memory cells in rows and columns. Each compute-in-memory cell of the array includes a memory element configured to store a weight value and a logic element coupled to a read line of the memory element. The logic element is configured to receive an input data value from an external data line and generate an output signal representing a result of a one-bit multiplication operation between the weight value and the input data value. The ASIC further includes a controller configured to manage the compute-in-memory operations of the array of compute-in-memory cells.

The foregoing general description of the illustrative embodiments and the following detailed description thereof are merely exemplary aspects of the teachings of this disclosure and are not restrictive.

Additional technical features and benefits are realized through the techniques of the disclosure. Embodiments and aspects of the disclosure are described in detail herein and are considered a part of the claimed subject matter. For a better understanding, refer to the detailed description and the drawings.

### BRIEF DESCRIPTION OF THE DRAWINGS

The following description will provide details of preferred embodiments with reference to the following figures, wherein:

FIG. 1 is a block diagram that illustrates a compute-in-memory cell with a memory element and a logic element, in accordance with an embodiment of the disclosure;

FIG. 2 is a diagram that illustrates a compute-in-memory cell configured for digital compute-in-memory operations, in accordance with an embodiment of the disclosure;

FIG. 3 is a diagram that illustrates a compute-in-memory cell with an inverting buffer arrangement, in accordance with an embodiment of the disclosure;

FIG. 4 is a diagram that illustrates a compute-in-memory cell configured for analog compute-in-memory operations, in accordance with an embodiment of the disclosure;

FIG. 5 is a diagram that illustrates a compute-in-memory cell with a current source and an integrator element, in accordance with an embodiment of the disclosure;

FIG. 6 is a diagram that illustrates a compute-in-memory cell with a static random access memory based memory element, in accordance with an embodiment of the disclosure;

FIG. 7 is a block diagram that illustrates an application-specific integrated circuit for compute-in-memory operations, in accordance with an embodiment of the disclosure; and

FIG. 8 is a flowchart depicting a method for performing compute-in-memory operations, in accordance with an embodiment of the disclosure.

### DETAILED DESCRIPTION

Modern computing systems increasingly rely on memory-intensive operations, particularly for applications such as neural network inference, signal processing, and machine learning workloads. Conventional computing architecture separates memory storage from computational logic, requiring data to be transferred between memory and processing units for each operation. This separation creates a data movement bottleneck that consumes substantial energy and limits overall system performance. As computational workloads continue to grow in scale and complexity, the energy and latency costs associated with data movement have become increasingly significant factors in system design.

Dynamic random access memory (DRAM) and static random access memory (SRAM) represent two widely deployed memory technologies, each with distinct characteristics. DRAM cells typically comprise a switch (transistor) and a capacitor, with typical implementations having switches on both sides to provide separate read and write paths. The switch is controlled by a word line, and data is accessed via the bit line. DRAM cells are organized in arrays where cells share bit lines (columns) and word lines (rows). DRAM provides high density and low leakage with fast writes, but requires constant refresh operations to maintain stored data, has destructive reads where the value must be written back after reading, and exhibits slow read times due to weak signals from the capacitor. SRAM elements typically comprise back-to-back inverters forming a latch (6T or 7T memory cell), where the latch is self-reinforcing such that once a value is stored, the value circulates and maintains itself. To write a new value to an SRAM element, the latch loop must be disabled via a switch. SRAM provides faster access times, non-destructive reads, and requires no refresh, but consumes more area per cell (4+ transistors) and has higher power consumption due to connections to supply and ground. The complementary read paths in SRAM can be used for error correction (ECC RAM), where if both paths read the same value, it indicates the bit is corrupted. Embedded DRAM (eDRAM) represents a compromise between these technologies, implementing DRAM-style cells (switch and capacitor) within logic processes to achieve better density than SRAM while maintaining compatibility with logic fabrication. While dedicated DRAM processes use special techniques such as vertical capacitors to achieve high capacitance in dense areas, eDRAM in logic processes has poorer capacitance but still achieves better density than SRAM and uses the same refresh circuits as conventional DRAM. Beyond these conventional technologies, alternative memory technologies have emerged, including resistive RAM and magnetic RAM, each offering different trade-offs in terms of density, speed, power consumption, and non-volatility.

The present disclosure describes a compute-in-memory cell that integrates memory storage with computational logic within a single cell structure. The compute-in-memory cell comprises a memory element configured to store a weight value and a logic element coupled to a read line of the memory element. The logic element is configured to receive an input data value from an external data line and generate an output signal based on the input data value and the weight value. The output signal represents a result of a one-bit multiplication operation between the weight value and the input data value. By performing computation directly within the memory structure, the compute-in-memory cell reduces data movement overhead compared to conventional architectures where data is transferred between separate memory and processing units.

The memory element of the compute-in-memory cell may be implemented using various memory technologies. In some embodiments, the memory element is an embedded dynamic random access memory (eDRAM) element including a pair of control switches and a capacitor configured to store the weight value. For eDRAM implementations, a buffer may be coupled between the memory element and the logic element to provide a read path that enables non-destructive reading of the weight value, as conventional DRAM reading destroys the stored charge in the capacitor. In some embodiments, the memory element is a static random access memory (SRAM) element including back-to-back inverters as a latch, where the latched value from the inverters is used directly for compute operations without requiring a buffer. The memory element may also be implemented using resistive RAM technology or magnetic RAM technology as alternatives to eDRAM or SRAM. The flexibility in memory element implementation allows the compute-in-memory cell to be adapted for different application requirements and fabrication processes, including future memory cell types.

The logic element of the compute-in-memory cell may be implemented in various configurations, with the requirement being that the output signal represents the result of the one-bit multiplication operation between the weight value and the input data value. In some embodiments, the logic element is an AND gate, and the output signal is a digital value. In some embodiments, the logic element is a NOR gate used in conjunction with inverting buffers, where the inversion is performed prior to entering the cell for efficiency. In some embodiments, the logic element comprises switches configured to perform the one-bit multiplication operation. The compute-in-memory cell supports both digital compute-in-memory (DCIM) implementations, where outputs are accumulated using digital adders, and analog compute-in-memory (ACIM) implementations, where outputs are accumulated using current summation on a shared bus and integration, with an analog-to-digital converter required to obtain the digital result.

The compute-in-memory cell architecture provides several advantages for computational workloads. By storing weight values in memory elements and performing multiplication operations locally, the compute-in-memory cell reduces the energy consumed by data transfers between memory and processing units. The integration of memory and computation improves computational density by eliminating the need for separate memory and logic blocks. The support for various memory technologies, including eDRAM, SRAM, resistive RAM, and magnetic RAM, allows the compute-in-memory cell to be deployed across different technology nodes and application domains. Arrays of compute-in-memory cells may be arranged to perform multiply-accumulate operations or matrix-vector multiplication operations, which form the computational foundation of many neural network and signal processing applications, including tensor operations, convolutions, and filter operations. The architecture enables one matrix to remain loaded in memory while another is passed row by row for computation. The read and write switches of the memory cells are not utilized for compute operations, as the buffer (in DRAM implementations) or latch (in SRAM implementations) stores the value used for compute, with the memory cell address corresponding one-to-one with the multiply logic address without requiring separate mapping, thereby simplifying the addressing scheme for the array of compute-in-memory cells.

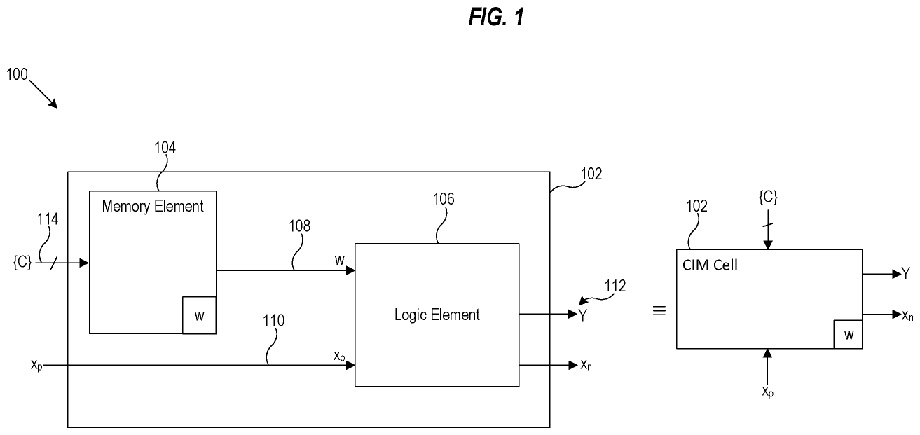

FIG. 1 is a block diagram 100 that illustrates a compute-in-memory cell 102 configured to perform in-memory multiplication operations, in accordance with an embodiment of the disclosure. With reference to FIG. 1, there is shown the block diagram 100, which depicts an architecture of the compute-in-memory cell 102 integrating memory storage with computational logic within a single cell structure. The compute-in-memory cell 102 comprises a memory element 104 configured to store a weight value, denoted as “w” in the block diagram 100, and a logic element 106 coupled to a read line 108 of the memory element 104. The logic element 106 is configured to receive an input data value from an external data line 110 and generate an output signal 112 based on the input data value and the weight value. The output signal 112 represents a result of a one-bit multiplication operation between the weight value and the input data value. The compute-in-memory cell 102 further comprises an output data line configured to provide the input data value as an output for feeding a next compute-in-memory cell in an array configuration. By performing computation directly within the memory structure, the compute-in-memory cell 102 reduces data movement overhead compared to conventional architectures where data is transferred between separate memory and processing units.

The memory element 104 may be implemented using various memory technologies to store the weight value. In some embodiments, the memory element 104 is an embedded dynamic random access memory (eDRAM) element including a pair of control switches and an integrator element, such as a capacitor, configured to store the weight value. The eDRAM implementation provides a compromise between SRAM and DRAM, implementing DRAM-style cells within logic processes, thereby providing improved density relative to SRAM while maintaining compatibility with logic fabrication processes. In some embodiments, the memory element 104 is a static random access memory (SRAM) element including back-to-back inverters as a latch, wherein the latch is self-reinforcing such that once a value is stored, the value circulates and maintains itself without requiring refresh operations. The memory element 104 may also be implemented using resistive RAM technology, magnetic RAM technology, or other memory technologies suitable for storing binary values. The flexibility in memory element implementation allows the compute-in-memory cell 102 to be adapted for different application requirements and fabrication processes. The memory element 104 receives control signals 114, represented as {C} in the block diagram 100, which manage operations such as reading and writing of the weight value. The memory element 104 comprises one or more read and write lines for accessing the stored weight value during memory operations.

With continued reference to FIG. 1, the read line 108 carries the weight value w from the memory element 104 to the logic element 106. The read line 108 provides a path for the stored weight value to be accessed by the logic element 106 during compute operations. In some implementations, particularly for eDRAM implementations, a buffer may be coupled between the memory element 104 and the logic element 106 to provide a read path that enables non-destructive reading of the weight value, as conventional DRAM reading destroys the stored charge in the capacitor. The buffer enables the weight value to be read repeatedly without disturbing the stored charge, which is advantageous for compute-in-memory applications wherein the same weight may be utilized repeatedly. In SRAM implementations, the logic element 106 may be directly coupled to the SRAM element, and the logic element 106 is configured to receive the weight value as a latched output of the SRAM element for the one-bit multiplication operation without requiring an intermediate buffer, as the latched value from the back-to-back inverters is utilized directly for compute operations.

The external data line 110 provides the input data value, denoted as “xₚ” in the block diagram 100, to the logic element 106 for computation purposes. The input data value is received from a data line different from the one or more read and write lines of the memory element 104. This separation of the external data line 110 from the memory read and write paths allows the weight value to remain stored in the memory element 104 while input data values are applied for computation. The read and write switches of the memory element 104 are not utilized for compute operations, as the buffer (in eDRAM implementations) or latch (in SRAM implementations) stores the value utilized for compute. The compute-in-memory cell 102 further comprises an output data line that provides the input data value as an output, denoted as “xₙ” in the block diagram 100, for feeding a next compute-in-memory cell in an array configuration. The external data line 110 may be connected as a wire that broadcasts the input data value to multiple compute-in-memory cells in an array configuration, thereby enabling matrix-vector multiplication operations.

The logic element 106 performs the one-bit multiplication operation between the weight value received from the read line 108 and the input data value received from the external data line 110. In some embodiments, the logic element 106 is an AND gate, and the output signal 112 is a digital value. The AND gate implementation produces a digital output that represents the logical AND of the weight value and the input data value, which corresponds to the one-bit multiplication result. In some embodiments, the logic element 106 comprises switches configured to perform the one-bit multiplication operation. The switch-based implementation may include a first switch configured to activate based on the weight value and a second switch configured to activate based on the input data value. The first switch and the second switch are connected in series to a current source, and current flows through the switches only when both the weight value and the input data value are active. In some embodiments, the logic element 106 is a NOR gate utilized in conjunction with inverting buffers. The inversion is performed prior to entering the cell, and the NOR gate receives an inverted version of the weight value and an inverted version of the input data value to produce an output equivalent to the AND operation.

As shown in FIG. 1, the output signal 112, denoted as Y, represents the result of the one-bit multiplication operation between the weight value w and the input data value xₚ. The compute-in-memory cell 102 supports both digital compute-in-memory (DCIM) implementations, wherein outputs are accumulated using digital adders, and analog compute-in-memory (ACIM) implementations, wherein outputs are accumulated using current summation on a shared bus and integration. In DCIM implementations, the output signal 112 is a digital value when the logic element 106 is implemented as an AND gate or equivalent digital logic. In ACIM implementations, the outputs from multiple cells are coupled together, and the currents from all cells combine on a shared bus. The output signal 112 may be utilized to control current flow, wherein the output signal 112 enables a switch coupled between an integrator element and a current source, allowing current to flow from the current source to the integrator element for accumulation. The integrator element is configured to convert the current to a voltage signal, and an analog-to-digital converter (ADC) element is configured to convert the voltage signal to a digital output representing the result of the one-bit multiplication operation.

The block diagram 100 also shows an equivalent representation of the compute-in-memory cell 102 on the right side, depicted as a CIM Cell. This equivalent representation illustrates the same compute-in-memory cell 102 receiving the control signals 114, the input data value xₚ from the external data line 110, and storing the weight value w in the memory element 104, while producing the output signal 112 denoted as Y and the output data value xₙ for feeding a next compute-in-memory cell. This abstracted view demonstrates how the compute-in-memory cell 102 functions as an integrated unit that combines memory storage and computational capabilities for performing in-memory multiplication operations. Arrays of compute-in-memory cells 102 may be arranged in rows and columns to perform matrix-vector multiplication operations, which form the computational foundation of many neural network and signal processing applications, including tensor operations, convolutions, and filter operations. The architecture enables one matrix to remain loaded in memory while another is passed row by row for computation.

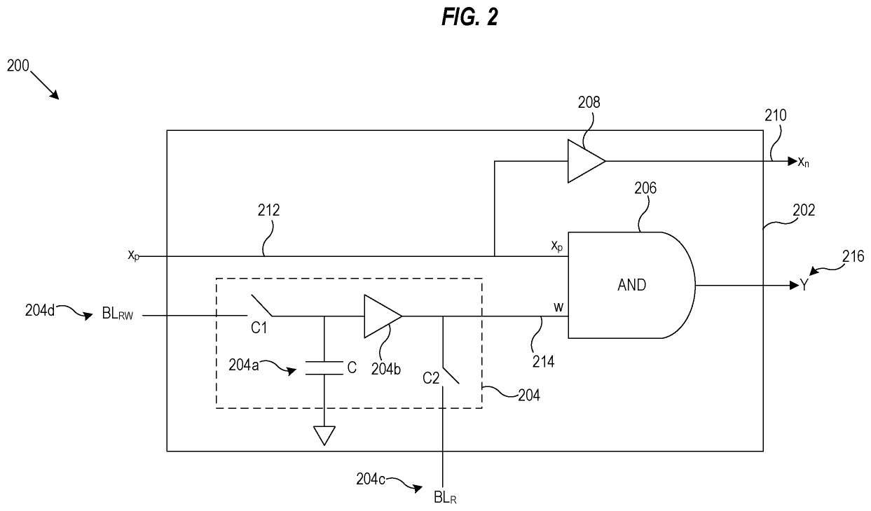

FIG. 2 is a diagram 200 that illustrates a compute-in-memory cell 202 configured for digital compute-in-memory operations, in accordance with an embodiment of the disclosure. FIG. 2 is explained in conjunction with elements from FIG. 1. With reference to FIG. 2, there is shown the diagram 200. The diagram 200 depicts the circuit architecture that enables in-memory multiplication operations by integrating a memory element 204 with a logic element 206. The compute-in-memory cell 202 comprises the memory element 204 configured to store a weight value. The memory element 204 is an embedded dynamic random access memory (eDRAM) element including a pair of control switches and an integrator element implemented as a capacitor 204a configured to store the weight value. The eDRAM implementation provides a compromise between SRAM and DRAM, implementing DRAM-style cells within logic processes, thereby providing improved density relative to SRAM while maintaining compatibility with logic fabrication processes. The memory element 204 further comprises a buffer 204b coupled between the eDRAM element and the logic element 206, bitlines read 204c, and bitlines write 204d for accessing the stored weight value during memory operations.

With continued reference to FIG. 2, the capacitor 204a is configured to store the weight value within the compute-in-memory cell 202. The capacitor 204a is connected to the bitlines write 204d and the bitlines read 204c through control switches. A first control switch, labeled C1 in the diagram 200, is positioned between the capacitor 204a and the bitlines write 204d, while a second control switch, labeled C2 in the diagram 200, is positioned between the capacitor 204a and the bitlines read 204c. The control switches C1 and C2 enable selective access to the capacitor 204a for write and read operations, respectively. The storing of the weight value comprises storing the weight value in the capacitor 204a of the eDRAM element. The weight values stored in the memory element 204 are assumed to be relatively static during computation, while input data values applied to the logic element 206 are dynamic.

The buffer 204b is coupled between the eDRAM element and the logic element 206. The buffer 204b is a high impedance (high-Z) buffer configured to provide a read path that enables non-destructive reading of the weight value from the capacitor 204a. The buffer 204b may be implemented using various circuit configurations, including, but not limited to, a source follower, a voltage follower, or a unity-gain buffer. In conventional DRAM, reading a value destroys the stored charge in the capacitor. The buffer 204b addresses this limitation by enabling the weight value to be read after the buffer 204b, leaving the charge stored in the capacitor 204a undisturbed. When reading, the write path is disabled, and when writing, the read path is disabled, ensuring the capacitor 204a stored value is not destroyed during read operations. This non-destructive reading capability is advantageous for compute-in-memory applications wherein the same weight value may be utilized repeatedly during computation. The output of the buffer 204b connects to a read line 214 of the memory element 204, which feeds into the logic element 206. The buffer 204b is specific to DRAM implementations and is not required for SRAM implementations, where the latched value from the inverters is used directly for compute operations.

The logic element 206 is coupled to the read line 214 of the memory element 204. The logic element 206 is implemented as an AND gate in the configuration shown in the diagram 200, and the output signal is a digital value. The logic element 206 is configured to receive two inputs: the weight value from the read line 214 and an input data value from an external data line 212. The weight value and the input data value are each one-bit value. The external data line 212 carries the input data value, labeled as xₚ in the diagram 200, which is provided to the logic element 206 for the multiplication operation. The input data value is received from a data line different from the bitlines read 204c and bitlines write 204d of the memory element 204, as those paths are utilized for weight storage and refresh operations. The logic element 206 is configured to generate an output signal 216, labeled as Y in the diagram 200, based on the input data value and the weight value. The output signal 216 represents a result of a one-bit multiplication operation between the weight value and the input data value. Reading the weight value through the buffer 204b coupled between the eDRAM element and the logic element 206 enables the multiplication operation to be performed without disturbing the stored weight value. The read and write switches of the memory element 204 are not utilized for compute operations, as the buffer 204b stores the value utilized for compute, with memory cell addresses corresponding one-to-one with multiply logic addresses.

As further shown in FIG. 2, a buffer 208 is positioned at the output of the buffer 204b, providing an external data output 210 labeled as xₙ in the diagram 200. xₙ is same as xₚ. This configuration allows the buffered weight value to be available at the external data output 210 while simultaneously being used by the logic element 206 for computation. The circuit operates such that when the weight value is stored in the capacitor 204a, the weight value may be read through the buffer 204b without disturbing the stored charge. The logic element 206 performs the AND operation between the weight value and the input data value received from the external data line 212, producing the output signal 216 that represents the result of the one-bit multiplication operation. In digital compute-in-memory (DCIM) implementations, the outputs from multiple compute-in-memory cells are accumulated using digital adders, wherein the external data line 212 may be connected as a wire that broadcasts the input data value to multiple compute-in-memory cells in an array configuration, thereby enabling matrix-vector multiplication operations.

The input data value received from the external data line 212 may be applied as a bit-spliced version where individual bits of a multi-bit input are applied sequentially to the weight at the logic element 206. When multi-bit input values are utilized, the bit-spliced version of the input is applied to the weight at the logic element 206 to produce the output signal 216 representing the result of the one-bit multiplication operation between the weight value and the input data value. In some embodiments, only the weight value is stored in the memory element 204, and the input data values are applied one bit at a time to the weight at the logic element 206. This bit-serial approach enables the compute-in-memory cell 202 to process multi-bit operands through sequential application of individual bits, with intermediate results stored in temporary memory locations for subsequent reconstruction. The process of combining partial products is performed by a reconstruction block that handles the shifting and addition of partial products to produce the final result. The architecture of the compute-in-memory cell 202 enables computation to be performed directly within the memory structure, reducing data movement overhead in applications such as matrix-vector multiplication operations, tensor operations, convolutions, and filter operations.

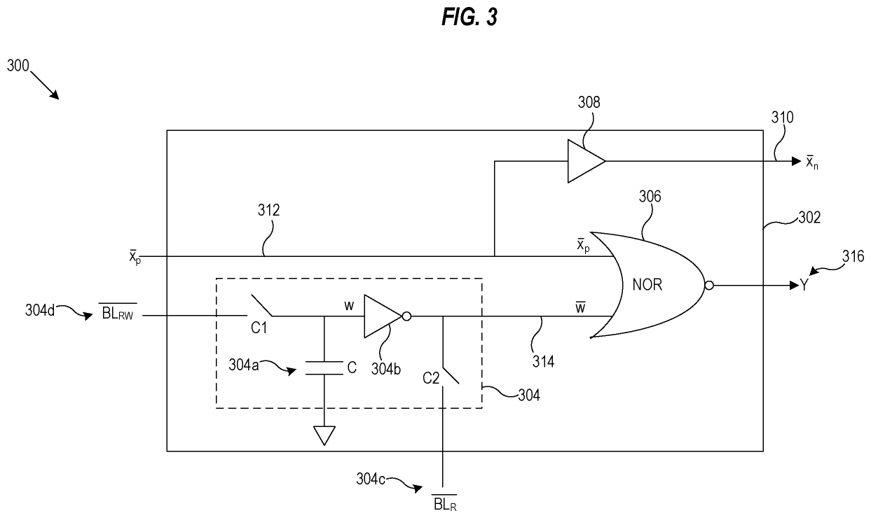

FIG. 3 is a diagram 300 that illustrates a compute-in-memory cell 302 configured with an inverting buffer arrangement for performing in-memory computation operations, in accordance with an embodiment of the disclosure. FIG. 3 is explained in conjunction with elements from FIG. 1 and FIG. 2. With reference to FIG. 3, there is shown the diagram 300. The diagram 300 depicts the circuit architecture wherein the compute-in-memory cell 302 comprises a memory element 304 configured to store a weight value and a logic element 306 coupled to a read line 314 of the memory element 304 to enable one-bit multiplication operations. The logic element 306 is a NOR gate in the configuration shown in the diagram 300. The compute-in-memory cell 302 further comprises an inverting buffer 304b coupled between the memory element 304 and the logic element 306, wherein the inverting buffer 304b is configured to output an inverted version of the weight value (w̅) stored in the memory element 304. The NOR gate implementation with inverting buffers represents an alternative logic configuration to the AND gate implementation, wherein the key requirement is that the output signal represents a result of a one-bit multiplication operation between the weight value and the input data value. The inversion is performed prior to entering the cell for efficiency, enabling the NOR gate to receive the inverted weight value w̅ and the inverted input data value x̅ to produce an output equivalent to the AND operation.

The memory element 304 includes a capacitor 304a configured to store the weight value w. The capacitor 304a is connected to an inverted write bit line 304d for write operations and an inverted read bit line 304c for read operations. Control switches are positioned between the capacitor 304a and the respective bit lines to enable selective access for write and read operations. The inverting buffer 304b is positioned between the capacitor 304a and the logic element 306, enabling the weight value to be read in inverted form (w̅) without disturbing the stored charge in the capacitor 304a. The memory element 304 provides a path for the stored weight value to be accessed by the logic element 306 during compute operations, with the inverting buffer 304b providing the inversion prior to the logic element 306. In some embodiments, the memory element 304 may be implemented using embedded dynamic random access memory (eDRAM) technology including a pair of control switches and the capacitor 304a configured to store the weight value, wherein the inverting buffer 304b serves the dual purpose of providing a read path that enables non-destructive reading of the weight value from the capacitor 304a and outputting the inverted version w̅ required by the NOR gate logic. The inverting buffer 304b is specific to DRAM implementations and enables the weight value to be read repeatedly without destroying the stored charge in the capacitor 304a.

With continued reference to FIG. 3, the logic element 306 is configured to receive the inverted version of the weight value (w̅) from the inverting buffer 304b coupled to the memory element 304 via the read line 314. The read line 314 is labeled with “w̅” in the diagram 300, indicating the inverted weight value path from the inverting buffer 304b to the logic element 306. The logic element 306 is also configured to receive an inverted input data value x̅ₚ from an external data line 312. The input data value is received as an inverted version of an input value (x) with the inversion performed prior to entering the cell. A buffer 308 is coupled to the external data line 312 and provides an external data output 310, which carries the inverted input data value x̅ₙ (same as x̅ₚ) to a next compute-in-memory cell in an array configuration. The external data line 312 carries the inverted input data value, labeled as “x̅ₚ” in the diagram 300, and the buffer 308 provides this inverted input data value to the next compute-in-memory cell. The input data value is received from a data line different from the inverted read bit line 304c and inverted write bit line 304d of the memory element 304, as those paths are utilized for weight storage and refresh operations. This separation allows the weight value to remain stored in the memory element 304 while input data values are applied for computation.

The logic element 306 is configured to generate an output signal 316 based on the inverted input data value x̅ₚ and the inverted version w̅ of the weight value. The output signal 316 is labeled as “Y” in the diagram 300. Due to the properties of the NOR gate combined with the inverted inputs w̅ and x̅ₚ, the output signal 316 represents a result of a one-bit multiplication operation between the original weight value w and the original input data value x. The NOR gate implementation achieves the same functional result as an AND gate implementation while utilizing the inverting characteristics of the buffer elements within the compute-in-memory cell 302. The separation of read and write paths, combined with the inverting buffer arrangement, enables non-destructive reading of the weight value during compute operations. The read and write switches of the memory element 304 are not utilized for compute operations, as the inverting buffer 304b stores the value utilized for compute, with memory cell addresses corresponding one-to-one with multiply logic addresses. When multi-bit input values are utilized, the bit-spliced version of the input may be applied to the weight at the logic element 306 to produce the output signal 316 representing the result of the one-bit multiplication operation between the weight value and the input data value.

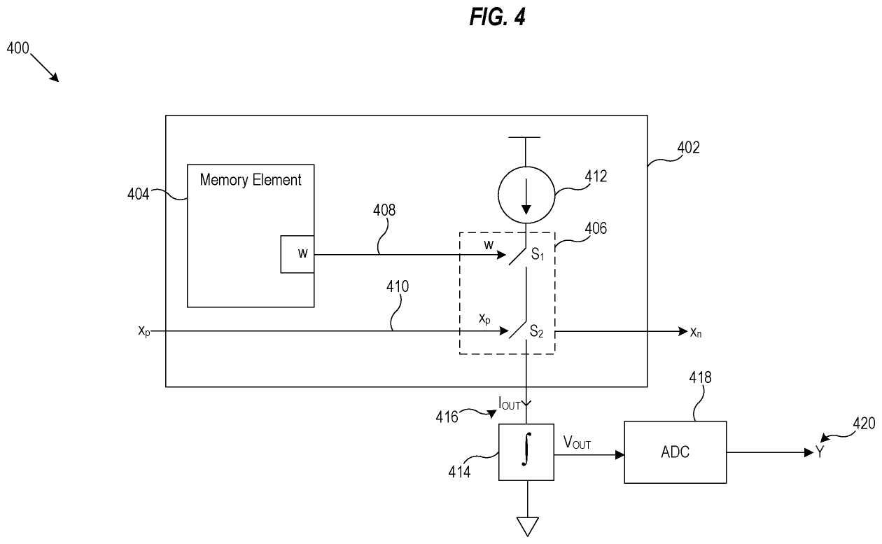

FIG. 4 is a diagram 400 that illustrates a compute-in-memory cell 402 configured for analog compute-in-memory operations, in accordance with an embodiment of the disclosure. FIG. 4 is explained in conjunction with elements from FIG. 1, FIG. 2, and FIG. 3. With reference to FIG. 4, there is shown the diagram 400. The diagram 400 depicts the integration of memory and computational elements with analog signal processing components for performing multiplication operations. The compute-in-memory cell 402 comprises a memory element 404 configured to store a weight value w. The memory element 404 may be implemented using various memory technologies, including embedded dynamic random access memory (eDRAM) element including a pair of control switches and an integrator element, such as a capacitor, configured to store the weight value, static random access memory (SRAM) element including back-to-back inverters as a latch, resistive RAM, or magnetic RAM, as described previously. The memory element 404 is coupled to a logic element 406 through a read line 408 of the memory element 404, wherein the read line 408 carries the weight value w to the logic element 406. The logic element 406 is depicted within a dashed boundary in the diagram 400 and comprises switches configured to perform the one-bit multiplication operation. Specifically, the logic element 406 comprises a first switch S1 and a second switch S2 connected in series to a current source 412. The first switch S1 is configured to activate based on the weight value received through the read line 408, and the second switch S2 is configured to activate based on an input data value xₚ received from an external data line 410. The logic element 406 is configured to receive the input data value from the external data line 410 and generate an output signal based on the input data value and the weight value, wherein the output signal represents a result of a one-bit multiplication operation between the weight value and the input data value. The switch-based implementation represents an alternative to the AND gate or NOR gate implementations described previously, wherein the key requirement is that the output signal represents the result of the one-bit multiplication operation (w×xₚ). The compute-in-memory cell 402 further comprises an output data line configured to provide the input data value as an output xₙ for feeding a next compute-in-memory cell in an array configuration.

With continued reference to FIG. 4, the current source 412 is connected to the logic element 406 and provides current to the series-connected first switch S1 and second switch S2. When both the first switch S1 and the second switch S2 are activated based on their respective input values, a current 416 labeled as I_{OUT} flows from the current source 412 through the switches to an integrator element 414. The integrator element 414 is configured to integrate, based on the activation of the first switch S1 and the second switch S2, the current 416 from the current source 412 to produce a voltage signal V_{OUT}. The integrator element 414 may be implemented using various circuit configurations, including, but not limited to, a capacitor, an operational amplifier-based integrator circuit, a switched-capacitor integrator, or other suitable current-to-voltage conversion circuits. The integrator element 414 is connected to ground, completing the current path. The series connection of the first switch S1 and the second switch S2 implements the multiplication logic, wherein the current 416 flows only when both the weight value and the input data value xₚ activate their respective switches. This configuration enables the compute-in-memory cell 402 to perform the one-bit multiplication operation in the analog domain. In some embodiments, the integrator element 414 may be positioned at the end of a column of compute-in-memory cells to convert the combined current from multiple cells to a voltage signal.

The voltage signal V_{OUT} from the integrator element 414 is provided to an ADC element 418, which is an analog-to-digital converter (ADC) element configured to convert the voltage signal to a digital output 420 labeled as Y in the diagram 400. The ADC element 418 may be implemented using various analog-to-digital converter architectures, including, but not limited to, a successive approximation register (SAR) ADC, a flash ADC, a sigma-delta ADC, a pipeline ADC, or other suitable analog-to-digital conversion circuits. The ADC element 418 is configured to convert the voltage signal to the digital output 420 representing the result of the one-bit multiplication operation between the weight value and the input data value xₚ. The ADC element 418 is required in analog compute-in-memory implementations to obtain the digital result from the accumulated analog signal.

As further shown in FIG. 4, the configuration of the compute-in-memory cell 402 enables analog accumulation of multiplication results. In the analog compute-in-memory (ACIM) implementation, outputs from multiple compute-in-memory cells 402 may be coupled together on a shared bus where currents naturally sum without requiring a separate adder circuit. The currents from all cells combine on the shared bus, forming a bus of current sources for accumulation. This current summation approach differs from digital compute-in-memory (DCIM) implementations, which utilize digital adders for accumulation. The integrator element 414 accumulates the current over time and converts the combined current to the voltage signal V_{OUT}. In some embodiments, the analog compute-in-memory implementation may operate in the current domain without an integrator, with the ADC element 418 directly converting the current signal. The ADC element 418 converts the accumulated analog signal to the digital output 420 for further processing. The analog compute-in-memory implementation shares the same basic memory element structure with buffer and multiplication logic as described previously with respect to the digital compute-in-memory implementations, while utilizing current summation and integration for accumulation rather than digital adders. The weight values stored in the memory element 404 are assumed to be relatively static during computation, while the input data values applied through the external data line 410 are dynamic. The input data value xₚ is received from the external data line 410, which is a data line different from the one or more read and write lines of the memory element 404, thereby enabling the weight value to remain stored in the memory element 404 while input data values are applied for computation. The output data line provides the input data value as an output xₙ for feeding a next compute-in-memory cell in an array configuration.

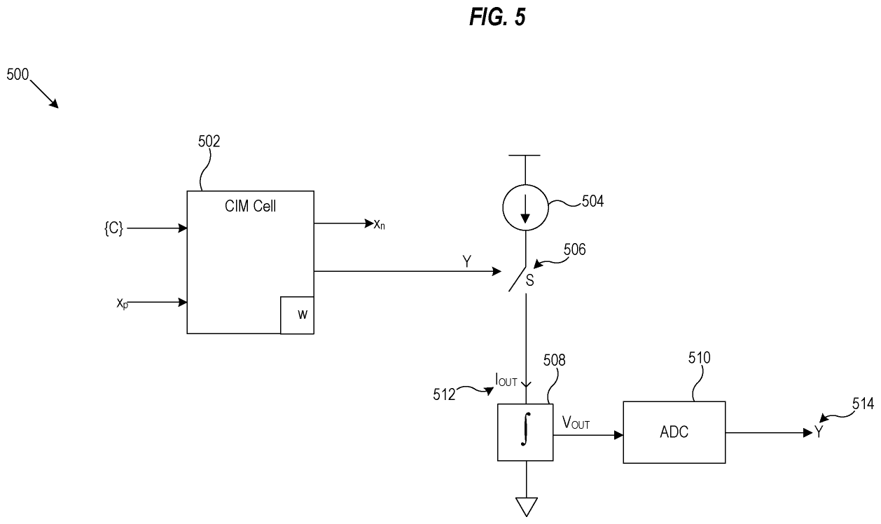

FIG. 5 is a diagram 500 that illustrates a compute-in-memory cell 502 with a current source 504 and an integrator element 508, in accordance with an embodiment of the disclosure. FIG. 5 is explained in conjunction with elements from FIG. 1, FIG. 2, FIG. 3, and FIG. 4. With reference to FIG. 5, there is shown the diagram 500. The diagram 500 depicts the compute-in-memory cell 502 receiving a control signal {C} and an input data value x from an external data line, with the compute-in-memory cell 502 configured to store a weight value w in a memory element. The compute-in-memory cell 502 generates an output signal Y based on the stored weight value w and the input data value xₚ. The output signal Y represents a result of a one-bit multiplication operation between the weight value and the input data value. The compute-in-memory cell 502 further comprises an output data line configured to provide the input data value as an output xₙ for feeding a next compute-in-memory cell in an array configuration. The compute-in-memory cell 502 comprises a memory element configured to store the weight value and a logic element coupled to a read line of the memory element, as described previously with respect to FIG. 1, FIG. 2, FIG. 3, and FIG. 4. The logic element is configured to receive the input data value from the external data line and generate the output signal based on the input data value and the weight value. The memory element may be implemented using various memory technologies, including embedded dynamic random access memory (eDRAM) element including a pair of control switches and an integrator element, such as a capacitor, configured to store the weight value, static random access memory (SRAM) element including back-to-back inverters as a latch, resistive RAM, or magnetic RAM, as described previously.

With continued reference to FIG. 5, the compute-in-memory cell 502 further comprises a switch 506 coupled between the integrator element 508 and the current source 504. The output signal from the compute-in-memory cell 502 is a digital value that feeds into the switch 506. The switch 506 is coupled to the output Y of the compute-in-memory cell 502 and is configured to be enabled based on the output signal from the compute-in-memory cell 502. The switch 506, based on being enabled by the digital value, is configured to allow current to flow from the current source 504 to the integrator element 508. When the switch 506 is enabled by the output Y, a current 512 labeled as I_{OUT} flows from the current source 504 through the switch 506 to the integrator element 508. The current source 504 provides the current 512 that is gated by the switch 506 based on the result of the one-bit multiplication operation from the compute-in-memory cell 502. In this configuration, the current source 504 is attached to the cell output, and the switch 506 controls the current path based on the result of the one-bit multiplication operation between the weight value and the input data value.

The integrator element 508 is configured to convert the current 512 to a voltage signal V_{OUT}. The integrator element 508 is connected to ground and produces the voltage signal V_{OUT} at an output of the integrator element 508. The integrator element 508 accumulates the current 512 over time to produce an analog voltage signal. In some embodiments, the integrator element 508 may be positioned at the end of a column of compute-in-memory cells to convert the combined current from multiple cells to a voltage signal. An output of the integrator element 508 is coupled to an ADC element 510, which is an analog-to-digital converter (ADC) element configured to convert the voltage signal V_{OUT} to a digital output 514 labeled as Y. The ADC element 510 is configured to convert the voltage signal to the digital output 514 representing the result of the one-bit multiplication operation between the weight value w stored in the memory element of the compute-in-memory cell 502 and the input data value xₚ. The ADC element 510 is required in analog compute-in-memory implementations to obtain the digital result from the accumulated analog signal.

As further shown in FIG. 5, the configuration of the compute-in-memory cell 502 with the current source 504, the switch 506, the integrator element 508, and the ADC element 510 enables analog accumulation of computation results. The current source 504 provides the current 512 that is gated by the switch 506 based on the result of the one-bit multiplication operation from the compute-in-memory cell 502. The integrator element 508 is configured to integrate, based on the activation of the switch 506, the current 512 from the current source 504 to produce the analog voltage signal V_{OUT}, which is subsequently digitized by the ADC element 510 to produce the digital output 514 representing the result of the one-bit multiplication operation. This configuration enables the compute-in-memory cell 502 to perform the one-bit multiplication operation between the weight value and the input data value and provide an analog output that may be accumulated with outputs from other compute-in-memory cells in an array configuration for matrix-vector multiplication operations. The analog compute-in-memory implementation shown in the diagram 500 enables current summation on a shared bus where currents from multiple compute-in-memory cells naturally sum without requiring a separate digital adder circuit, as described previously with respect to FIG. 4. In some embodiments, the analog compute-in-memory implementation may operate in the current domain without an integrator, with the ADC element 510 directly converting the current signal. The outputs from multiple compute-in-memory cells 502 may be coupled together on a shared bus, forming a bus of current sources for accumulation, wherein the currents from all cells combine on the shared bus for integration by the integrator element 508. The output data line provides the input data value xₚ as an output xₙ for feeding a next compute-in-memory cell in the array configuration.

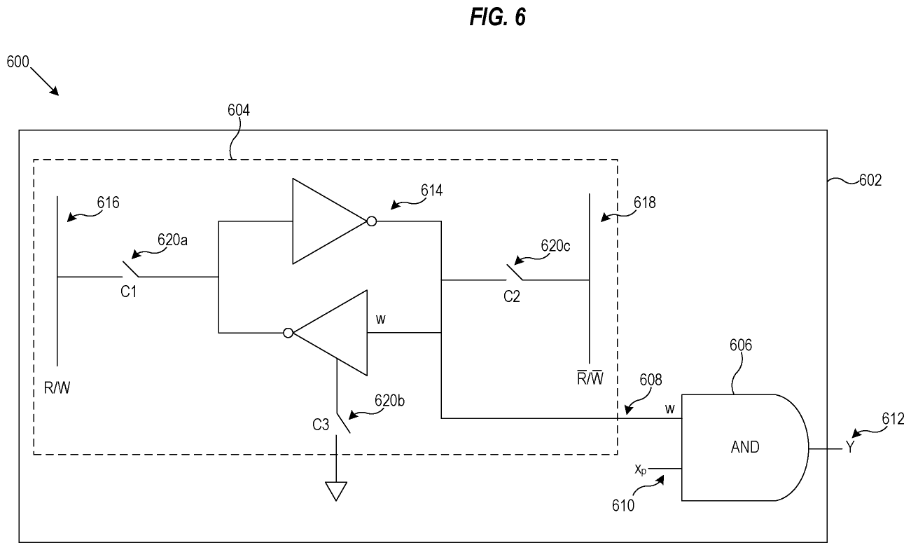

FIG. 6 is a diagram 600 that illustrates a compute-in-memory cell 602 with a static random access memory (SRAM)-based memory element, in accordance with an embodiment of the disclosure. FIG. 6 is explained in conjunction with elements from FIG. 1, FIG. 2, FIG. 3, FIG. 4, and FIG. 5. With reference to FIG. 6, there is shown the diagram 600. The diagram 600 depicts the circuit architecture wherein the compute-in-memory cell 602 comprises a memory element 604 configured to store a weight value and a logic element 606 coupled to a read line 608 of the memory element 604. The memory element 604 is a static random access memory (SRAM) element including back-to-back inverters as a latch 614. In some embodiments, the SRAM element may be implemented as a 6T (six-transistor) or 7T (seven-transistor) memory cell configuration. The latch 614 is configured to store the weight value in a self-reinforcing manner, wherein once a value is stored, the value circulates and maintains itself without requiring refresh operations. This self-reinforcing characteristic of the latch 614 provides faster access times and non-destructive reads compared to DRAM implementations, although at the cost of higher area consumption per cell (4+ transistors) and higher power consumption due to connections to supply and ground.

With continued reference to FIG. 6, the logic element 606 is directly coupled to the SRAM element, and the logic element 606 is configured to receive the weight value as a latched output of the SRAM element for the one-bit multiplication operation. The logic element 606 is configured to receive an input data value from an external data line 610 and generate an output signal 612 based on the input data value and the weight value. The output signal 612 represents a result of a one-bit multiplication operation between the weight value and the input data value. The logic element 606 is depicted as an AND gate in the diagram 600, and the output signal 612 is a digital value. In some embodiments, the logic element 606 may comprise switches configured to perform the one-bit multiplication operation, as described previously with respect to FIG. 4. The read line 608 is labeled with “w” in the diagram 600, indicating the weight value path from the latch 614 to the logic element 606. The external data line 610 is labeled with “xₚ” in the diagram 600, indicating the input data path. The input data value is received from the external data line 610, which is a data line different from the R/W line 616 and the Inverted R/W line 618 of the memory element 604, thereby enabling the weight value to remain stored in the memory element 604 while input data values are applied for computation. The output signal 612 is labeled “Y” in the diagram 600.

The memory element 604 comprises one or more read and write lines for accessing the stored weight value during memory operations. The memory element 604 includes a first control switch 620a coupled to an R/W line 616, a second control switch 620b coupled to the latch 614, and a third control switch 620c coupled to an Inverted R/W line 618. The first control switch 620a and the third control switch 620c are positioned on opposite sides of the latch 614, providing access paths for read and write operations. The second control switch 620b is coupled between the back-to-back inverters of the latch 614 and is configured to disable the latch loop during write operations. To write a new value to the SRAM element, the latch loop must be disabled via the control switches, allowing the new value to overwrite the existing stored state. The configuration allows for complementary read paths through the memory element 604. The complementary read paths in the SRAM element may be utilized for error correction (ECC RAM), wherein if both paths read the same value, the condition indicates the bit is corrupted.

The control signals C1, C2, and C3 operate in specific states to control the operation of the compute-in-memory cell 602. The control signal C1 controls the first control switch 620a coupled to the R/W line 616, the control signal C2 controls the third control switch 620c coupled to the Inverted R/W line 618, and the control signal C3 controls the second control switch 620b that disables the latch loop. When C1, C2, and C3 are all off, the compute-in-memory cell 602 enables compute operation using the stored weight value from the latch 614. When C1 and C2 are on with C3 off, the compute-in-memory cell 602 enables read and write operations, wherein both the R/W line 616 and the Inverted R/W line 618 paths are available simultaneously, providing complementary access paths. When C3 is on, the latch loop is disabled to allow a new weight value to be written to the latch 614, wherein compute operation is not recommended during write operations.

In some embodiments, the read operation may be performed in parallel with the multiplication operation when the read control signals C1 and C2 are enabled. This parallel read and compute capability enables the weight value to be read from the memory element 604 through the complementary read paths while simultaneously being utilized by the logic element 606 for the one-bit multiplication operation with the input data value received from the external data line 610. The circuit operates such that the latched value from the latch 614 is provided directly to the logic element 606 through the read line 608 for compute operations, while the first control switch 620a, the second control switch 620b, and the third control switch 620c are utilized for separate read and write operations to the memory element 604. This configuration enables non-destructive access to the stored weight value during computation, as the latched output is used directly without disturbing the stored state. The SRAM implementation does not require a buffer between the memory element 604 and the logic element 606, as the latched value from the back-to-back inverters forming the latch 614 is utilized directly for compute operations. In some embodiments, the memory element 604 may alternatively be implemented using resistive RAM technology or magnetic RAM technology, each offering different trade-offs in terms of density, speed, power consumption, and non-volatility. In some embodiments, the input data value received from the external data line 610 may be applied as a bit-spliced version where individual bits of a multi-bit input are applied sequentially to the weight at the logic element 606, with intermediate results stored in temporary memory locations for subsequent reconstruction by a reconstruction block that handles the shifting and addition of partial products to produce the final result. Arrays of compute-in-memory cells 602 may be arranged in rows and columns to perform matrix-vector multiplication operations, which form the computational foundation of many neural network and signal processing applications, including tensor operations, convolutions, and filter operations, wherein one matrix remains loaded in memory while another is passed row by row for computation.

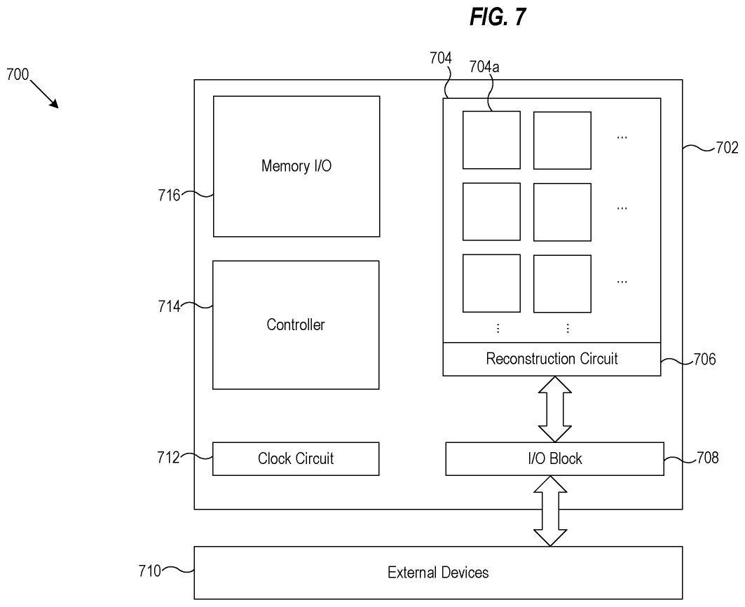

FIG. 7 is a block diagram 700 that illustrates an application-specific integrated circuit (ASIC) 702 for compute-in-memory operations, in accordance with an embodiment of the disclosure. FIG. 7 is explained in conjunction with elements from FIG. 1, FIG. 2, FIG. 3, FIG. 4, FIG. 5, and FIG. 6. With reference to FIG. 7, there is shown the block diagram 700. The block diagram 700 depicts the application-specific integrated circuit 702 comprising an arrangement of an array of compute-in-memory cells 704 in rows and columns. Each compute-in-memory cell 704a of the array of compute-in-memory cells 704 comprises a memory element configured to store a weight value and a logic element coupled to a read line of the memory element, as described previously with respect to FIG. 1, FIG. 2, FIG. 3, FIG. 4, FIG. 5, and FIG. 6. The memory element may be implemented using various memory technologies, including, but not limited to, embedded dynamic random access memory (eDRAM) elements including a pair of control switches and a capacitor configured to store the weight value, static random access memory (SRAM) elements including back-to-back inverters as a latch, resistive RAM, or magnetic RAM, as described previously. The logic element is configured to receive an input data value from an external data line and generate an output signal representing a result of a one-bit multiplication operation between the weight value and the input data value. In some embodiments, the logic element may be implemented as an AND gate, wherein the output signal is a digital value. In some embodiments, the logic element may be implemented as a NOR gate used in conjunction with inverting buffers, wherein the inverting buffer is configured to output an inverted version of the weight value. In some embodiments, the logic element comprises switches configured to perform the one-bit multiplication operation.

The application-specific integrated circuit 702 comprises a tensor unit that includes the array of compute-in-memory cells 704 arranged with adder circuits positioned between columns. The tensor unit enables the application-specific integrated circuit 702 to perform tensor operations, convolutions, and filter operations that form the computational foundation of many neural network and signal processing applications. The application-specific integrated circuit 702 further comprises a controller 714 configured to manage the compute-in-memory operations of the array of compute-in-memory cells 704. The controller 714 coordinates the overall operation of the application-specific integrated circuit 702, including timing and sequencing of read, write, and compute operations across the array of compute-in-memory cells 704. The data flow architecture of the application-specific integrated circuit 702 follows a path from the memory I/O 716 to the tensor unit comprising the array of compute-in-memory cells 704, then to the reconstruction circuit 706 for combining partial products, and subsequently to additional processing stages. The output of the reconstruction circuit 706 may connect to a host processor or memory through the I/O block 708 and external devices 710 for further processing or storage of computation results.

With continued reference to FIG. 7, the application-specific integrated circuit 702 includes a reconstruction circuit 706 coupled to the array of compute-in-memory cells 704. The reconstruction circuit 706 is configured to combine partial products from the compute-in-memory cells 704a to produce final computation results. The reconstruction circuit 706 includes temporary memory locations for storing intermediate results during bitwise multiplication operations. The reconstruction circuit 706 performs shifting and addition of partial products to produce the final multiplication result. When multi-bit operands are processed through the array of compute-in-memory cells 704, individual bits are applied sequentially to the weight values stored in the memory elements as a bit-spliced version, and the reconstruction circuit 706 handles the shifting and addition of the resulting partial products to produce the final result. In some embodiments, only the weight value is stored in the memory element, and the input data values are applied one bit at a time to the weight at the logic element. The reconstruction circuit 706 is connected to an I/O block 708, which facilitates communication between the application-specific integrated circuit 702 and external devices 710. The I/O block 708 provides bidirectional communication with the reconstruction circuit 706 and enables data exchange with the external devices 710 for receiving input data and outputting computation results.

The array of compute-in-memory cells 704 includes adder circuits positioned between columns to perform accumulation of partial products from multiple cells. The adder circuit accepts multiple one-bit inputs and produces an output with bit width determined by the number of inputs. In some embodiments, two inputs produce a two-bit output, four inputs produce a three-bit output, and 1024 inputs produce a ten-bit output. The adder circuit is fixed at design time based on the number of multiply-accumulate operations supported by the application-specific integrated circuit 702. The adder circuits enable the array of compute-in-memory cells 704 to perform accumulation operations for matrix-vector multiplication, wherein outputs from cells in each column are summed to produce partial results that are subsequently processed by the reconstruction circuit 706. In digital compute-in-memory (DCIM) implementations, the outputs from the compute-in-memory cells 704a are accumulated using the digital adders. In analog compute-in-memory (ACIM) implementations, the outputs from the compute-in-memory cells 704a may alternatively be accumulated using current summation on a shared bus, wherein the currents from all cells combine on the shared bus forming a bus of current sources for accumulation. In such ACIM implementations, the logic element comprises a first switch and a second switch connected in series to a current source, wherein the first switch is configured to activate based on the weight value and the second switch is configured to activate based on the input data value. An integrator element is configured to integrate, based on the activation of the first switch and the second switch, current from the current source to produce a voltage signal. An analog-to-digital converter (ADC) element is configured to convert the voltage signal to a digital output representing the result of the one-bit multiplication operation.

As further shown in FIG. 7, the application-specific integrated circuit 702 includes a clock circuit 712 configured to provide timing signals for synchronizing operations within the application-specific integrated circuit 702. The clock circuit 712 provides timing signals to the controller 714, the array of compute-in-memory cells 704, and the reconstruction circuit 706 to coordinate the compute-in-memory operations. A memory I/O 716 is coupled to the array of compute-in-memory cells 704 and is configured to handle weight storage and refresh operations for the memory elements within the compute-in-memory cells 704a. In some embodiments, for eDRAM implementations, the memory I/O 716 manages periodic refresh operations to maintain stored data in the integrator elements, such as capacitors, and a buffer is coupled between the eDRAM element and the logic element, wherein the buffer is configured to provide a read path that enables non-destructive reading of the weight value from the integrator element, such as a capacitor. For SRAM implementations, no refresh operations are required as the latched values are self-reinforcing, and the logic element is directly coupled to the SRAM element, wherein the logic element is configured to receive the weight value as a latched output of the SRAM element for the one-bit multiplication operation. The controller 714 interfaces with the memory I/O 716 to control read and write operations to the array of compute-in-memory cells 704. The memory element comprises one or more read and write lines, and the input data value is received from a data line different from the one or more read and write lines. The read and write switches of the memory cells are not utilized for compute operations, as the buffer (in eDRAM implementations) or latch (in SRAM implementations) stores the value utilized for compute. The memory cell address corresponds one-to-one with the multiply logic address without requiring separate mapping, thereby simplifying the addressing scheme for the array of compute-in-memory cells 704.

The compute-in-memory cell 704a may be used for vector dot product operations. The array of compute-in-memory cells 704 enables vector dot product operations by storing weight values in the memory elements of the compute-in-memory cells 704a and applying input data values through the external data lines. The weight values stored in the memory elements are assumed to be relatively static during computation, while the input data values applied through the external data lines are dynamic. The outputs from the compute-in-memory cells 704a in each column are accumulated by the adder circuits to produce the dot product result. The compute-in-memory cell 704a may also be used for tensor multiplication operations. The application-specific integrated circuit 702 includes a tensor unit comprising the array of compute-in-memory cells 704 and associated logic for performing tensor operations. The tensor unit enables the application-specific integrated circuit 702 to perform tensor operations, convolutions, and filter operations that form the computational foundation of many neural network and signal processing applications. By performing computation directly within the memory structure, the application-specific integrated circuit 702 reduces data movement overhead compared to conventional architectures where data is transferred between separate memory and processing units.

For matrix-vector multiplication, one matrix is stored in the memory cells while the other matrix is passed row by row through the input lines. The weight values stored in the memory elements of the compute-in-memory cells 704a represent one matrix, and the input data values applied through the external data lines represent the other matrix. The architecture enables one matrix to remain loaded in memory while another is passed row by row for computation. The input data values are broadcast across rows of the compute-in-memory cells 704a, and each compute-in-memory cell 704a computes the product of the stored weight value and the input data value. In some embodiments, the external data line may be connected as a wire that broadcasts the input data value to multiple compute-in-memory cells in the array configuration. The column outputs are accumulated by the adder circuits, and the reconstruction circuit 706 combines the partial products to produce the final matrix-vector multiplication result.

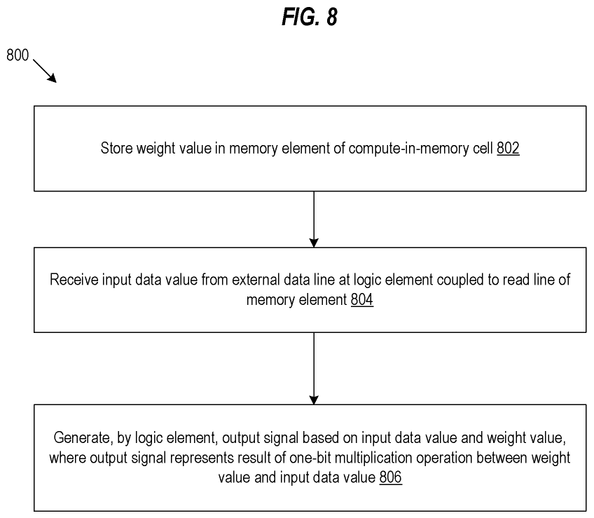

FIG. 8 is a diagram that illustrates a flowchart 800 depicting a method for performing compute-in-memory operations, in accordance with an embodiment of the disclosure. FIG. 8 is explained in conjunction with elements from FIG. 1, FIG. 2, FIG. 3, FIG. 4, FIG. 5, FIG. 6, and FIG. 7. With reference to FIG. 8, there is shown the flowchart 800. The operations of the exemplary method may be executed by any computing system, for example, by the application-specific integrated circuit 702 of FIG. 7 or by any system incorporating the compute-in-memory cell 102 of FIG. 1, the compute-in-memory cell 202 of FIG. 2, the compute-in-memory cell 302 of FIG. 3, the compute-in-memory cell 402 of FIG. 4, the compute-in-memory cell 502 of FIG. 5, or the compute-in-memory cell 602 of FIG. 6. The operations of the flowchart 800 may start at 802.

At 802, the operations include storing a weight value in a memory element of a compute-in-memory cell. In an embodiment of the disclosure, the weight value is stored in the memory element 104 of the compute-in-memory cell 102 as described with respect to FIG. 1. The memory element may be implemented using various memory technologies, including embedded dynamic random access memory (eDRAM) elements, static random access memory (SRAM) elements, resistive RAM, or magnetic RAM, as described previously. In some embodiments, the memory element is an eDRAM element, and the storing of the weight value comprises storing the weight value in an integrator element, such as a capacitor, of the eDRAM element, as described with respect to the memory element 204 of FIG. 2 and the memory element 304 of FIG. 3. In some embodiments, the memory element is an SRAM element including back-to-back inverters forming a latch, as described with respect to the memory element 604 of FIG. 6, wherein the latch 614 stores the weight value in a self-reinforcing manner. The weight values stored in the memory element are assumed to be relatively static during computation, while input data values applied to the logic element are dynamic. Following 802, the operations proceed to 804.

At 804, the operations include receiving an input data value from an external data line at a logic element coupled to a read line of the memory element. In an embodiment of the disclosure, the logic element 106 of the compute-in-memory cell 102 receives the input data value from the external data line 110, as described with respect to FIG. 1. The logic element is coupled to the read line 108 of the memory element 104, which carries the weight value from the memory element to the logic element. The input data value is received from a data line different from the one or more read and write lines of the memory element, thereby enabling the weight value to remain stored in the memory element while input data values are applied for computation. In some embodiments, the method further comprises reading the weight value through a buffer coupled between the eDRAM element and the logic element, wherein the buffer provides a read path that enables non-destructive reading of the weight value, as described with respect to the buffer 204b of FIG. 2 and the inverting buffer 304b of FIG. 3. In some embodiments, the memory element is an SRAM element, and the method further comprises receiving, by the logic element, the weight value as a latched output of the SRAM element, as described with respect to the compute-in-memory cell 602 of FIG. 6. Following 804, the operations proceed to 806.

At 806, the operations include generating, by the logic element, an output signal based on the input data value and the weight value, wherein the output signal represents a result of a one-bit multiplication operation between the weight value and the input data value. In an embodiment of the disclosure, the logic element 106 generates the output signal 112 based on the input data value received from the external data line 110 and the weight value stored in the memory element 104, as described with respect to FIG. 1. In some embodiments, the logic element is an AND gate, and the output signal is a digital value, as described with respect to the logic element 206 of FIG. 2 and the logic element 606 of FIG. 6. In some embodiments, the logic element is a NOR gate, and the method further comprises receiving the inverted version of the weight value from an inverting buffer coupled to the memory element and receiving the input data value as an inverted version of an input value, as described with respect to the logic element 306 of FIG. 3. In some embodiments, the generating of the output signal comprises activating a first switch by the weight value and activating a second switch by the input data value, wherein the first switch and the second switch are connected in series to a current source, integrating a current from the current source to produce a voltage signal based on the activating of the first switch and the second switch, and converting the voltage signal to a digital output using an analog-to-digital converter (ADC) element, as described with respect to the compute-in-memory cell 402 of FIG. 4 and the compute-in-memory cell 502 of FIG. 5.

With continued reference to FIG. 8, the method for performing compute-in-memory operations enables computation to be performed directly within the memory structure, reducing data movement overhead compared to conventional architectures where data is transferred between separate memory and processing units. The method may be performed by each compute-in-memory cell 704a within the array of compute-in-memory cells 704 of the application-specific integrated circuit 702, as described with respect to FIG. 7. When the method is performed by multiple compute-in-memory cells in an array configuration, the outputs from the compute-in-memory cells may be accumulated using digital adders in digital compute-in-memory (DCIM) implementations or using current summation on a shared bus in analog compute-in-memory (ACIM) implementations. The reconstruction circuit 706 may combine partial products from the compute-in-memory cells to produce final computation results for matrix-vector multiplication operations. The method enables the application-specific integrated circuit 702 to perform tensor operations, convolutions, and filter operations that form the computational foundation of many neural network and signal processing applications.

Reference throughout this specification to “an example” means that a particular feature, structure, or characteristic described in connection with the example is included in at least one embodiment of the present invention. Thus, appearances of the phrase “in an example” in various places throughout this specification are not necessarily all referring to the same embodiment.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on its presentation in a common group without indications to the contrary. In addition, various embodiments and examples of the present invention may be referred to herein along with alternatives for the various components thereof. It is understood that such embodiments, examples, and alternatives are not to be construed as de facto equivalents of one another but are to be considered as separate and autonomous representations of the present invention.

Although the foregoing has been described in some detail for purposes of clarity, it will be apparent that certain changes and modifications may be made without departing from the principles thereof. It should be noted that there are many alternative ways of implementing both the processes and apparatuses described herein. Accordingly, the present embodiments are to be considered illustrative and not restrictive, and the invention is not to be limited to the details given herein but may be modified within the scope and equivalents of the appended claims.

Those having skill in the art will appreciate that many changes may be made to the details of the above-described embodiments without departing from the underlying principles of the invention. The scope of the present invention should, therefore, be determined only by the following claims.

What is claimed is:

1. A compute-in-memory cell, comprising:
a memory element configured to store a weight value; and
a logic element coupled to a read line of the memory element, wherein the logic element is configured to:
receive an input data value from an external data line; and
generate an output signal based on the input data value and the weight value, wherein the output signal represents a result of a one-bit multiplication operation between the weight value and the input data value.

2. The compute-in-memory cell of claim 1, wherein the logic element is an AND gate, and the output signal is a digital value.

3. The compute-in-memory cell of claim 1, wherein the logic element comprises switches configured to perform the one-bit multiplication operation.

4. The compute-in-memory cell of claim 1, wherein the memory element is an embedded dynamic random access memory (eDRAM) element including a pair of control switches and a capacitor configured to store the weight value.

5. The compute-in-memory cell of claim 4, further comprising a buffer coupled between the eDRAM element and the logic element, wherein the buffer is configured to provide a read path that enables non-destructive reading of the weight value from the capacitor.

6. The compute-in-memory cell of claim 1, wherein the memory element is a static random access memory (SRAM) element including back-to-back inverters as a latch.

7. The compute-in-memory cell of claim 6, wherein the logic element is directly coupled to the SRAM element, and the logic element is configured to receive the weight value as a latched output of the SRAM element for the one-bit multiplication operation.

8. The compute-in-memory cell of claim 1, wherein:
the logic element comprises a first switch and a second switch connected in series to a current source,
the first switch is configured to activate based on the weight value and the second switch is configured to activate based on the input data value, and
the compute-in-memory cell further comprises:
an integrator element configured to integrate, based on the activation of the first switch and the second switch, current from the current source to produce a voltage signal; and
an analog-to-digital converter (ADC) element configured to convert the voltage signal to a digital output representing the result of the one-bit multiplication operation.

9. The compute-in-memory cell of claim 1, further comprising a switch coupled between an integrator element and a current source,
wherein the output signal is a digital value that feeds into the switch,
wherein the switch, based on being enabled by the digital value, is configured to allow current to flow from the current source to the integrator element,
wherein the integrator element is configured to convert the current to a voltage signal, and
wherein an output of the integrator element is coupled to an analog-to-digital converter (ADC) element, which is configured to convert the voltage signal to a digital output representing the result of the one-bit multiplication operation.

10. The compute-in-memory cell of claim 1, wherein the logic element is a NOR gate.

11. The compute-in-memory cell of claim 10, further comprising an inverting buffer coupled between the memory element and the logic element, wherein the inverting buffer is configured to output an inverted version of the weight value.

12. The compute-in-memory cell of claim 11, wherein the logic element is configured to:
receive the inverted version of the weight value from the inverting buffer coupled to the memory element;
receive the input data value as an inverted version of an input value; and
generate the output signal based on the input data value and the inverted version of the weight value.

13. The compute-in-memory cell of claim 1, wherein the memory element comprises one or more read and write lines, and the input data value is received from a data line different from the one or more read and write lines.

14. A method for performing compute-in-memory operations, comprising:
storing a weight value in a memory element of a compute-in-memory cell;
receiving an input data value from an external data line at a logic element coupled to a read line of the memory element; and
generating, by the logic element, an output signal based on the input data value and the weight value, wherein the output signal represents a result of a one-bit multiplication operation between the weight value and the input data value.

15. The method of claim 14, wherein the logic element is an AND gate, and the output signal is a digital value.

16. The method of claim 14, wherein the memory element is an embedded dynamic random access memory (eDRAM) element, and wherein the storing of the weight value comprises storing the weight value in a capacitor of the eDRAM element.

17. The method of claim 16, further comprising reading the weight value through a buffer coupled between the eDRAM element and the logic element, wherein the buffer provides a read path that enables non-destructive reading of the weight value.

18. The method of claim 14, wherein the memory element is a static random access memory (SRAM) element including back-to-back inverters forming a latch, and wherein the method further comprises receiving, by the logic element, the weight value as a latched output of the SRAM element.

19. The method of claim 14, wherein the generating of the output signal comprises:
activating a first switch by the weight value and activating a second switch by the input data value, wherein the first switch and the second switch are connected in series to a current source;
integrating a current from the current source to produce a voltage signal based on the activating of the first switch and the second switch; and
converting the voltage signal to a digital output using an analog-to-digital converter (ADC) element.

20. An application-specific integrated circuit (ASIC) for compute-in-memory operations, comprising:
an arrangement of an array of compute-in-memory cells in rows and columns, wherein each compute-in-memory cell of the array of compute-in-memory cells comprises:
a memory element configured to store a weight value; and
a logic element coupled to a read line of the memory element, wherein the logic element is configured to:
receive an input data value from an external data line; and
generate an output signal representing a result of a one-bit multiplication operation between the weight value and the input data value; and
a controller configured to manage the compute-in-memory operations of the array of compute-in-memory cells.
